(19) United States
(12) Patent Application Publication
(10) Pub. No.: US 2026/0101824 A1
(43) Pub. Date: Apr. 9, 2026

(54) SEMICONDUCTOR PACKAGE

(71) Applicant: SAMSUNG ELECTRONICS CO., LTD., SUWON-SI (KR)

(72) Inventors: Heejung Hwang, Suwon-si (KR); Youngdeuk Kim, Suwon-si (KR)

(21) Appl. No.: 19/273,404

(22) Filed: Jul. 18, 2025

(30) Foreign Application Priority Data
Sep. 4, 2024 (KR) 10-2024-0120316

(51) Int. Cl. H01L 23/00; H01L 25/065; H10B 80/00

(52) U.S. Cl. CPC H10W 90/00; H10B 80/00; H10W 72/07332; H10W 74/15; H10W 90/722; H10W 90/732

(57) ABSTRACT

The semiconductor package including a base chip, a plurality of first semiconductor chips each having a first horizontal width, and a plurality of second semiconductor chips each having a second horizontal width that is different from the first horizontal width. The plurality of first semiconductor chips and the plurality of second semiconductor chips are alternately stacked on the base chip. An adhesive layer is between adjacent semiconductor chips of the alternately stacked plurality of first semiconductor chips each of the plurality of first semiconductor chips and second semiconductor chips.

### CROSS-REFERENCE TO RELATED APPLICATION

This application claims priority under 35 U.S. C. § 119 to Korean Patent Application No. 10-2024-0120316, filed on Sep. 4, 2024 in the Korean Intellectual Property Office, the disclosure of which is incorporated by reference in its entirety herein.

### 1. TECHNICAL FIELD

The present inventive concept relates to a semiconductor package, and particularly, to a semiconductor package including a plurality of semiconductor chips stacked in the vertical direction.

### 2. DISCUSSION OF RELATED ART

The demand for portable devices has rapidly increased in the electronics product market. Accordingly, electronic components mounted in electronic products have become increasingly lightweight and miniaturized. For example, there has been an increase in demand for miniaturized and lightened semiconductor packages mounted in the electronic components to process high-capacity data with a small volume and reduced defects.

In addition, semiconductor packages have been developed having a plurality of semiconductor chips stacked in the vertical direction to reduce the size of the semiconductor package. Research is being conducted concerning maintaining structural reliability in such semiconductor packages even with an increased number of stacked semiconductor chips.

### SUMMARY

The present inventive concept provides a semiconductor package with increased reliability by reducing the temperature difference between an edge and the center of a semiconductor chip in a thermal compression bonding (TCB) process.

In addition, the problems to be solved by the technical idea of embodiments of the present inventive concept are not limited to the problem mentioned above, and other problems could be clearly understood by those of ordinary skill in the art from the description below.

According to an embodiment of the present inventive concept, the semiconductor package including a base chip, a plurality of first semiconductor chips each having a first horizontal width, and a plurality of second semiconductor chips each having a second horizontal width that is different from the first horizontal width. The plurality of first semiconductor chips and the plurality of second semiconductor chips are alternately stacked on the base chip. An adhesive layer is between adjacent semiconductor chips of the alternately stacked plurality of first semiconductor chips each of the plurality of first semiconductor chips and second semiconductor chips.

According to embodiment of the present inventive concept, a semiconductor package including a lower substrate having an external connection terminal on a lower surface thereof, a base chip on the lower substrate, a plurality of first semiconductor chips each having a first horizontal width, a plurality of second semiconductor chips each having a second horizontal width that is greater than the first horizontal width, a top-layer semiconductor chip having a height that is greater than a height of each second semiconductor chip of the plurality of second semiconductor chips and having a same horizontal width as the second horizontal width, an adhesive layer between adjacent semiconductor chips of the plurality of first semiconductor chips and the plurality of second semiconductor chips and between an uppermost first semiconductor chip among the plurality of first semiconductor chips and the top-layer semiconductor chip, the adhesive layer including a fillet portion extending in a horizontal direction, and a molding member filling gaps among the base chip, the plurality of first semiconductor chips, the plurality of second semiconductor chips, the top-layer semiconductor chip, and the adhesive layer on the lower substrate. The plurality of first semiconductor chips and each of the plurality of second semiconductor chips are alternately stacked on the base chip, the top-layer semiconductor chip is on the uppermost first semiconductor chip among the plurality of first semiconductor chips, the first horizontal width is less than a horizontal width of the adhesive layer, the second horizontal width is substantially same as the horizontal width of the adhesive layer, a difference between the second horizontal width and the first horizontal width is substantially same as a horizontal width of the fillet portion, and the plurality of first semiconductor chips, the plurality of second semiconductor chips, and the top-layer semiconductor chip are vertically stacked such that centers thereof in a horizontal direction overlap each other in a vertical direction.

According to an embodiment of the present inventive concept, there is provided a semiconductor package including a base chip, a plurality of first semiconductor chips each having a first horizontal width, and a plurality of second semiconductor chips each having a second horizontal width that is different from the first horizontal width, wherein first semiconductor chip structures each including the plurality of first semiconductor chips vertically stacked and the plurality of second semiconductor chips are alternately stacked on the base chip, and an adhesive layer is between adjacent first semiconductor chips of the plurality of first semiconductor chips and between each of the first semiconductor chip structures and each of the plurality of second semiconductor chips.

According to an embodiment of the present inventive concept, a semiconductor package includes a base chip, a plurality of first semiconductor chips each having a first core area and a first dummy area and a plurality of second semiconductor chips each having a second core area and a second dummy area. The first core area and the second core area have a same horizontal width as each other and the second dummy area has a larger horizontal width than a horizontal width of the first dummy area. The plurality of first semiconductor chips and the plurality of second semiconductor chips are alternately stacked on the base chip. An adhesive layer is between adjacent semiconductor chips of the alternately stacked plurality of first semiconductor chips and second semiconductor chips. The adhesive later includes a fillet portion that has a horizontal length equal to a difference between the horizontal lengths of the second dummy area and the first dummy area.

In an embodiment, the fillet portion is formed by a thermal compression process.

In an embodiment, side surfaces of each second semiconductor chip are aligned with side surfaces of the adhesive layer.

In an embodiment, the plurality of first semiconductor chips and the plurality of second semiconductor chips are vertically stacked such that horizontal centers of the plurality of first semiconductor chips and the plurality of second semiconductor chips overlap each other in a vertical direction.

### BRIEF DESCRIPTION OF THE DRAWINGS

Embodiments of the present inventive concept will be more clearly understood from the following detailed description taken in conjunction with the accompanying drawings in which:

FIG. 1 is a cross-sectional view schematically illustrating a semiconductor package according to an embodiment of the present inventive concept;

FIG. 2 is a cross-sectional view schematically illustrating a portion EX1 of FIG. 1 according to an embodiment of the present inventive concept;

FIG. 3 is a cross-sectional view schematically illustrating a portion EX2 of FIG. 1 according to an embodiment of the present inventive concept;

FIGS. 4 to 11 are cross-sectional views schematically illustrating, in a process order, a method of manufacturing a chip-stacked structure, according to embodiments of the present inventive concept;

FIG. 12 is a cross-sectional view schematically illustrating a semiconductor package according to an embodiment of the present inventive concept;

FIGS. 13 to 16 are cross-sectional views schematically illustrating, in a process order, a method of manufacturing a chip-stacked structure, according to an embodiment of the present inventive concept; and

FIG. 17 is a cross-sectional view schematically illustrating a semiconductor package according to an embodiment of the present inventive concept.

### DETAILED DESCRIPTION OF EMBODIMENTS

Hereinafter, embodiments of the present inventive concept are described in detail with reference to the accompanying drawings. Like reference numerals in the drawings denote like elements, and thus their repetitive description will be omitted.

The present inventive concept relates to a semiconductor package having first semiconductor chips and second semiconductor chips alternately stacked on a base chip. An adhesive layer is between each of the adjacent semiconductor chips of the alternately stacked first and second semiconductor chips. The first semiconductor chips have a horizontal width that is less than the horizontal width of the second semiconductor chips. Since the horizontal width of the second semiconductor chips is greater than the horizontal width of the first semiconductor chips, a preliminary adhesive layer which forms the adhesive layer may receive a relatively uniform heat at an edge portion and a central portion thereof during a manufacturing process to prevent the occurrence of non-wet resulting from a temperature difference in different portions of the adhesive layer.

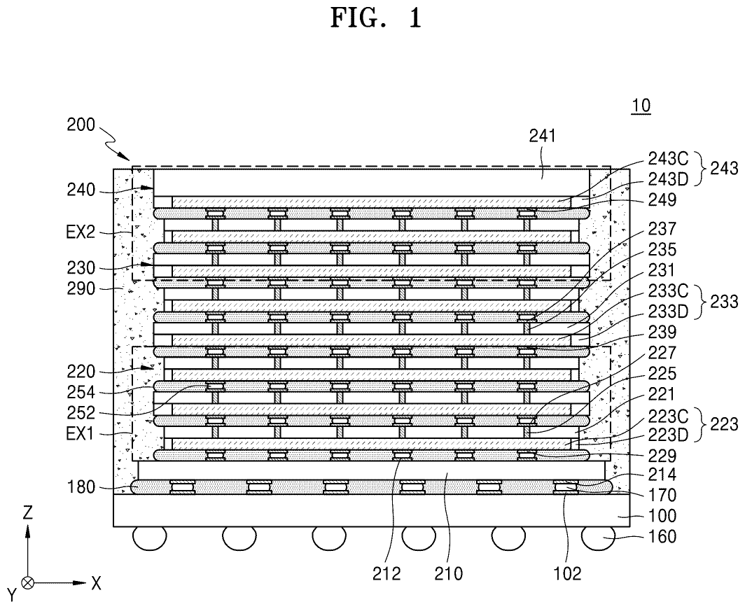

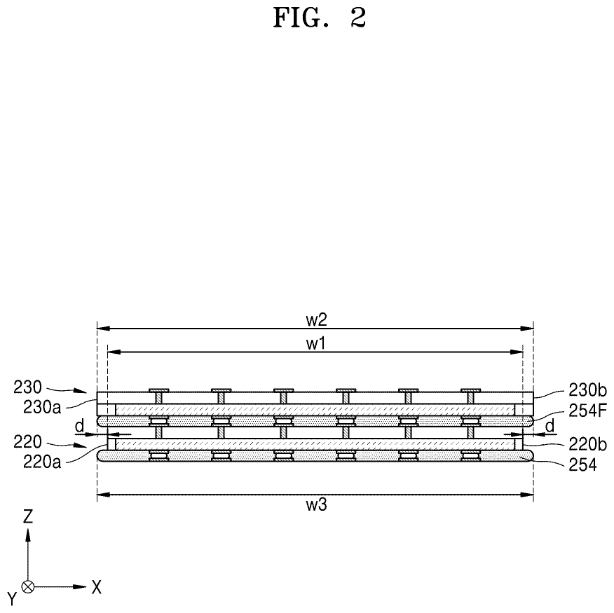

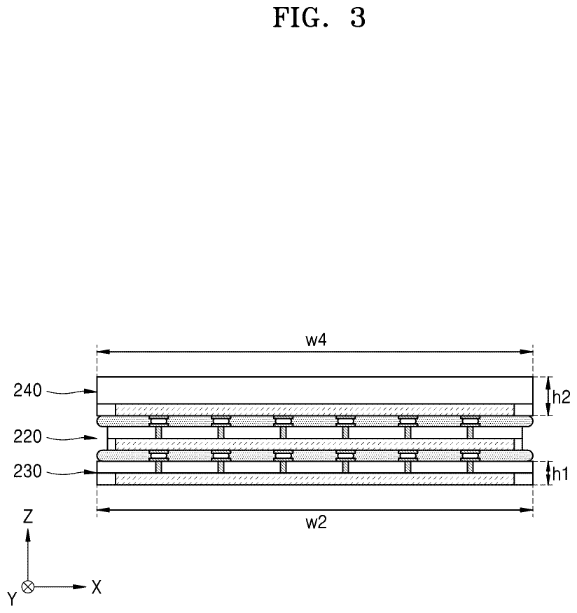

FIG. 1 is a cross-sectional view schematically illustrating a semiconductor package 10 according to an embodiment. FIG. 2 is a cross-sectional view schematically illustrating a portion EX1 of FIG. 1. FIG. 3 is a cross-sectional view schematically illustrating a portion EX2 of FIG. 1.

Referring to FIGS. 1 to 3, the semiconductor package 10 may include a lower substrate 100, an external connection terminal 160, a chip-stacked structure 200, and a molding member 290.

The lower substrate 100 of the semiconductor package 10 is a substrate on which the chip-stacked structure 200 is mounted, and may be under the chip-stacked structure 200 (e.g., in a −Z-axis direction). For example, the lower substrate 100 may be between the chip-stacked structure 200 and the external connection terminal 160 (e.g., in the Z-axis direction). The lower substrate 100 may be electrically connected to each of the chip-stacked structure 200 and the external connection terminal 160.

According to an embodiment, the lower substrate 100 may have a shape in which at least one of the upper surface and the lower surface of the lower substrate 100 is substantially flat. In the drawings, an X-axis direction and a Y-axis direction may indicate directions parallel to the upper surface or the lower surface of the lower substrate 100, which is a substantially flat surface, and the X-axis direction may be perpendicular to the Y-axis direction. A Z-axis direction may indicate a direction perpendicular to the upper surface or the lower surface of the lower substrate 100. For example, the Z-axis direction may be a direction perpendicular to an X-Y plane. However, embodiments of the present inventive concept are not necessarily limited thereto and the X-axis, Y-axis and Z-axis directions may cross each other at various different angles.

In addition, in the drawings below, a first horizontal direction, a second horizontal direction, and the vertical direction may be understood as follows. The first horizontal direction may be understood as the X-axis direction, the second horizontal direction may be understood as the Y-axis direction, and the vertical direction may be understood as the Z-axis direction.

The lower substrate 100 may include an insulating layer and a wiring formed inside the insulating layer. According to an embodiment, the lower substrate 100 may include a redistribution structure formed through a redistribution process. Herein, the wiring of the lower substrate 100 may be understood as a redistribution pattern, and the insulating layer of the lower substrate 100 may be understood as a redistribution insulating layer. In an embodiment, the wiring of the lower substrate 100 may include a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy of the metal. However, embodiments of the present inventive concept are not necessarily limited thereto, and in some embodiments, the wiring may be formed by stacking a metal or an alloy of the metal on a seed layer including Cu, Ti, titanium nitride, or titanium tungsten. In addition, the insulating layer of the lower substrate 100 may be formed of photo imageable dielectric (PID) or photosensitive polyimide (PSPI).

However, the lower substrate 100 is not necessarily limited thereto, and in some embodiments, the lower substrate 100 may be formed of a ceramic substrate, a printed circuit board (PCB), an organic substrate, or the like. In this embodiment, the wiring of the lower substrate 100 may include Cu, Ni, stainless steel, or beryllium copper, and the insulating layer of the lower substrate 100 may include at least one material selected from among flame retardant class 4 (FR-4), tetrafunctional epoxy, polyphenylene ether, epoxy/polyphenylene oxide, bismaleimide triazine (BT), Thermount, cyanate ester, polyimide, and liquid crystal polymer.

The external connection terminal 160 may be on the lower surface of the lower substrate 100 and electrically connected to the lower substrate 100 via a pad formed on the lower surface of the lower substrate 100. In an embodiment, the external connection terminal 160 may be electrically connected to wirings, formed in the lower substrate 100, via a substrate pad attached to the lower surface of the lower substrate 100. Since the external connection terminal 160 is beneath the lower substrate 100, the upper surface of the external connection terminal 160 may be in physical contact with the substrate pad attached to the lower surface of the lower substrate 100. The external connection terminal 160 may be electrically connected to an external device, for example, a motherboard, a PCB, a package substrate, or the like. Since the external connection terminal 160 is between the external device and the lower substrate 100, the lower surface of the external connection terminal 160 may be physically connected to the external device.

In an embodiment, the external connection terminal 160 may be formed as a solder ball. However, according to an embodiment, the external connection terminal 160 may have a structure including a pillar and solder. In an embodiment, the external connection terminal 160 may include at least one of Cu, silver (Ag), gold (Au), and Sn.

The chip-stacked structure 200 may be on the upper surface of the lower substrate 100. According to an embodiment, the chip-stacked structure 200 may be mounted on the upper surface of the lower substrate 100 through a first bump 170 in a flip chip manner. The first bump 170 may be between the chip-stacked structure 200 and the lower substrate 100 (e.g., in the Z-axis direction). The first bump 170 may electrically connect a connection pad 102 of the lower substrate 100 to a lower connection pad 214 of a base chip 210. In an embodiment, the first bump 170 may include a pillar structure, a ball structure, or a solder layer.

According to an embodiment, an under-fill material layer 180 surrounding the first bump 170 may be between the chip-stacked structure 200 and the lower substrate 100 (e.g., in the Z-axis direction). In an embodiment, the under-fill material layer 180 may include an epoxy resin formed by, for example, a capillary under-fill process. However, in some embodiments, the molding member 290 may directly fill the gap between the chip-stacked structure 200 and the lower substrate 100 by a molded under-fill process. In this embodiment, the under-fill material layer 180 may be omitted.

In an embodiment, the chip-stacked structure 200 of the semiconductor package 10 may include the base chip 210, a plurality of first semiconductor chips 220, a plurality of second semiconductor chips 230, and a top-layer semiconductor chip 240.

In an embodiment, the base chip 210 is a chip located at the lowermost end in the chip-stacked structure 200 and may be directly connected to the lower substrate 100 through the first bump 170. According to an embodiment, the base chip 210 may integrate signals of the plurality of first semiconductor chips 220, the plurality of second semiconductor chips 230, and the top-layer semiconductor chip 240 stacked on the base chip 210 and transmit the integrated signal to the outside (e.g., the external environment), or transmit a signal and power from the outside (e.g., the external environment) to the plurality of first semiconductor chips 220, the plurality of second semiconductor chips 230, and the top-layer semiconductor chip 240. Accordingly, the base chip 210 may be referred to as a buffer chip or a control chip in the specification.

The base chip 210 may include various types of individual devices. In an embodiment, the individual devices may include various microelectronics devices, such as a metal-oxide-semiconductor field effect transistor (MOSFET), such as a complementary metal-insulator-semiconductor (CMOS) transistor, a system large scale integration (LSI) chip, an image sensor, such as a CMOS imaging sensor (CIS), a micro-electro-mechanical system (MEMS), an active device, a passive device, and the like. In some embodiments, the base chip 210 may not include a memory cell. For example, in an embodiment a semiconductor device included in the base chip 210 may include a serial-parallel conversion circuit, a test logic circuit, such as a design for test (DFT) circuit, a joint test action group (JTAG) circuit, or a memory built-in self-test (MBIST) circuit, and a signal interface circuit, such as a physical layer device (PHY).

The plurality of first semiconductor chips 220 and the plurality of second semiconductor chips 230 may be alternately stacked on the base chip 210 (e.g., in the Z-axis direction).

The plurality of first semiconductor chips 220 may be defined as chips stacked on the base chip 210 in the vertical direction (e.g., the Z-axis direction) and beneath (e.g., directly below) or on (e.g., directly above) a second semiconductor chip 230 among a plurality of chips included in the chip-stacked structure 200. Since a first semiconductor chip 220 and a second semiconductor chip 230 are alternately stacked on the base chip 210, the plurality of first semiconductor chips 220 may be understood as chips between the base chip 210 and a second semiconductor chip 230 (e.g., in the Z-axis direction) and between every two adjacent second semiconductor chips 230 (e.g., in the Z-axis direction). In addition, as described below, the plurality of first semiconductor chips 220 may include a chip between a second semiconductor chip 230 and the top-layer semiconductor chip 240 (e.g., in a Z-axis direction).

For example, as shown in an embodiment of FIG. 1, the plurality of first semiconductor chips 220 may be provided as a total of four first semiconductor chips 220 alternately stacked with the plurality of second semiconductor chips 230 on the base chip 210. However, the number of first semiconductor chips 220 is not necessarily limited thereto, and the number of first semiconductor chips 220 may vary. For example, the number of first semiconductor chips 220 may be 6, 8, or the like according to the number of stacks of the chip-stacked structure 200. A first semiconductor chip 220 may be referred to as a memory chip or a core chip.

Each of the plurality of first semiconductor chips 220 may have a first horizontal width w1. In the specification, the term “horizontal width” indicates a length in the first horizontal direction (e.g., the X-axis direction) and/or a length in the second horizontal direction (e.g., the Y-axis direction). The first horizontal width w1 of each of the plurality of first semiconductor chips 220 may be different from a second horizontal width w2 of each of the plurality of second semiconductor chips 230. According to an embodiment, the first horizontal width w1 of each of the plurality of first semiconductor chips 220 may be less than the second horizontal width w2 of each of the plurality of second semiconductor chips 230. In addition, according to an embodiment, the first horizontal width w1 of the first semiconductor chips 220 and the second horizontal width w2 of the second semiconductor chips 230 may be less than the horizontal width of the base chip 210. A stacked structure of the plurality of first semiconductor chips 220 and the plurality of second semiconductor chips 230 is described below.

According to an embodiment, the first semiconductor chip 220 may include a first semiconductor substrate 221, a first semiconductor device layer 223, a first through electrode 225, a first upper connection pad 227, and a first lower connection pad 229. The first semiconductor substrate 221 may have a lower surface and an upper surface that are opposite to each other. The lower surface may be a surface facing the lower substrate 100. The lower surface may be referred to as an active surface, and the upper surface that is opposite to the lower surface may be referred to as an inactive surface.

In an embodiment, the first semiconductor substrate 221 may include silicon (Si), such as monocrystalline Si, polycrystalline Si, or amorphous Si. Alternatively, the first semiconductor substrate 221 may include a semiconductor element, such as germanium (Ge), or a compound semiconductor, such as silicon carbide (SiC), gallium arsenide (GaAs), indium arsenide (InAs), or indium phosphide (InP). In addition, the first semiconductor substrate 221 may have a silicon on insulator (SOI) structure. For example, the first semiconductor substrate 221 may include a buried oxide (BOX) layer. The first semiconductor substrate 221 may include a conductive area, such as an impurity-doped well or an impurity-doped structure. In addition, the first semiconductor substrate 221 may have various device isolation structures, such as a shallow trench isolation (STI) structure.

According to an embodiment, the first semiconductor device layer 223 may be formed on the lower surface that is the active surface of the first semiconductor substrate 221. In an embodiment, the first semiconductor device layer 223 may include a first core area 223C and a first dummy area 223D. In an embodiment, the first dummy area 223D may be disposed on lateral ends of the first semiconductor device layer 223 and the first core area 223C may be disposed on a central portion of the first semiconductor device layer 223. In an embodiment, individual devices may be formed in the first core area 223C of the first semiconductor device layer 223. The individual devices may include various microelectronics devices, e.g., a MOSFET, such as a CMOS transistor, an LSI chip, an image sensor, such as a CIS, an MEMS, an active device, a passive device, and the like. The first dummy area 223D of the first semiconductor device layer 223 may be formed of Si. Individual devices may not be formed in the first dummy area 223D of the first semiconductor device layer 223.

The first through electrode 225 may be formed to pass through the first semiconductor substrate 221 in the vertical direction (e.g., the Z-axis direction). In some embodiments, the first through electrode 225 may be formed to pass through a portion of the first semiconductor device layer 223 and the first semiconductor substrate 221. The first through electrode 225 may extend in the vertical direction (e.g., the Z-axis direction) from the first semiconductor device layer 223 towards the upper surface of the first semiconductor substrate 221 and may be electrically connected to wirings provided in the first semiconductor device layer 223. The first through electrode 225 may have a tapered shape having a horizontal width that gradually decreases or increases as the vertical level thereof increases. At least a portion of the first through electrode 225 may have a pillar shape. In an embodiment, the first through electrode 225 may be a through silicon via (TSV).

The first upper connection pad 227 may be on the upper surface of the first semiconductor substrate 221 (e.g., disposed directly thereon in the Z-axis direction), which is an inactive surface of the first semiconductor chip 220, and the first lower connection pad 229 may be on the lower surface of the first semiconductor device layer 223 (e.g., disposed directly thereon in the −Z-axis direction), which is an active surface of the first semiconductor chip 220. The first upper connection pad 227 may be electrically connected to the first through electrode 225. First lower connection pads 229 may be electrically connected to wirings of the first semiconductor device layer 223. In an embodiment, some first lower connection pads 229 may be electrically connected to corresponding first through electrodes 225, respectively.

According to an embodiment, the first semiconductor chip 220 may include a memory chip. The memory chip may be, for example, a volatile memory chip, such as dynamic random access memory (DRAM) or static random access memory (SRAM), or a non-volatile memory chip, such as phase-change random access memory (PRAM), magnetoresistive random access memory (MRAM), ferroelectric random access memory (FeRAM), or resistive random access memory (RRAM). However, the first semiconductor chip 220 is not necessarily limited thereto and may include a logic chip, such as a microprocessor, such as a central processing unit (CPU), a graphics processing unit (GPU), or an application processor (AP), an analog device, or a digital signal processor.

The plurality of second semiconductor chips 230 may be defined as chips on the upper surfaces or the lower surfaces of the plurality of first semiconductor chips 220 stacked in the vertical direction (e.g., the Z-axis direction). In an embodiment, a first semiconductor chip 220 may be a first semiconductor chip disposed on the base chip 210 (e.g., in the Z-axis direction), and second semiconductor chips 230 and first semiconductor chips 220 may be alternately disposed on the first semiconductor chip 220. Therefore, the plurality of second semiconductor chips 230 may be understood as chips between every two adjacent first semiconductor chips 220. Each of the plurality of second semiconductor chips 230 may have the second horizontal width w2 (e.g., length in the X-axis direction and/or Y-axis direction) that is different from the first horizontal width w1 of each of the plurality of first semiconductor chips 220. The second horizontal width w2 may be greater than the first horizontal width w1.

According to an embodiment, the second semiconductor chip 230 may include a second semiconductor substrate 231, a second semiconductor device layer 233, a second through electrode 235, a second upper connection pad 237, and a second lower connection pad 239. The second semiconductor substrate 231 may have a lower surface and an upper surface that are opposite to each other (e.g., in the Z-axis direction). The lower surface may be a surface facing the first semiconductor chip 220. The lower surface may be referred to as an active surface, and the upper surface that is opposite to the lower surface may be referred to as an inactive surface.

In an embodiment, the second semiconductor substrate 231 may include Si, such as monocrystalline Si, polycrystalline Si, or amorphous Si. The second semiconductor substrate 231 may have a greater length in a horizontal direction (e.g., the X-axis direction and/or the Y-axis direction) than the first semiconductor substrate 221.

The second semiconductor device layer 233 may be formed on the lower surface that is the active surface of the second semiconductor substrate 231. In an embodiment, the second semiconductor device layer 233 may include a second core area 233C and a second dummy area 233D. In an embodiment, the second dummy area 233D may be disposed on lateral ends of the second semiconductor device layer 233 and the second core area 233C may be disposed on a central portion of the second semiconductor device layer 233. According to an embodiment, individual devices may be formed in the second core area 233C. According to an embodiment, the second dummy area 233D may be formed of Si. Individual devices may not be formed in the second dummy area 233D.

According to an embodiment, the length of the second core area 233C in the horizontal direction (e.g., the X-axis direction and/or the Y-axis direction) may be substantially the same as the length of the first core area 223C in the horizontal direction (e.g., the X-axis direction and/or the Y-axis direction). In an embodiment, the length of the second dummy area 233D in the horizontal direction (e.g., the X-axis direction and/or the Y-axis direction) may be greater than the length of the first dummy area 223D in the horizontal direction (the X-axis direction and/or the Y-axis direction). However, the relative lengths of the second core area 233C and the second dummy area 233D and the relative lengths of the first core area 223C and the first dummy area 223D in the horizontal direction (e.g., the X-axis direction and/or the Y-axis direction) are not necessarily limited thereto, and the second core area 233C may be substantially the same as the first core area 223C.

The second through electrode 235 may be formed to pass through the second semiconductor substrate 231 in the vertical direction (e.g., the Z-axis direction). In some embodiments, the second through electrode 235 may be formed to pass through a portion of the second semiconductor device layer 233 and the second semiconductor substrate 231. The second through electrode 235 may extend in the vertical direction (e.g., the Z-axis direction) from the second semiconductor device layer 233 towards the upper surface of the second semiconductor substrate 231 and may be electrically connected to wirings provided in the second semiconductor device layer 233. The second through electrode 235 may have a tapered shape having a horizontal width that gradually decreases or increases as the vertical level thereof increases. At least a portion of the second through electrode 235 may have a pillar shape. In an embodiment, the second through electrode 235 may be a TSV.

The second upper connection pad 237 may be on the upper surface of the second semiconductor substrate 231 (e.g., disposed directly thereon in the Z-axis direction), which is an inactive surface of the second semiconductor chip 230, and the second lower connection pad 239 may be on the lower surface of the second semiconductor device layer 233 (e.g., disposed directly thereon in the −Z-axis direction), which is an active surface of the second semiconductor chip 230. The second upper connection pad 237 may be electrically connected to the second through electrode 235. Second lower connection pads 239 may be electrically connected to wirings of the second semiconductor device layer 233. Some second lower connection pads 239 may be electrically connected to corresponding second through electrodes 235, respectively, although such connections are not explicitly shown in FIG. 1.

In an embodiment, the top-layer semiconductor chip 240 may be stacked, in the vertical direction (e.g., the Z-axis direction), on the uppermost first semiconductor chip 220 among the plurality of first semiconductor chips 220 alternately stacked with the plurality of second semiconductor chips 230. For example, the top-layer semiconductor chip 240 may replace the uppermost second semiconductor chip 230 among the plurality of second semiconductor chips 230 alternately stacked with the plurality of first semiconductor chips 220. For example, the top-layer semiconductor chip 240 may be disposed in a position that would otherwise correspond to an uppermost second semiconductor chip 230 of the alternatingly stacked plurality of first and second semiconductor chips 220, 230 of the chip-stacked structure 200 and is disposed in such position instead of an uppermost second semiconductor chip 230.

In an embodiment, the top-layer semiconductor chip 240 may include a top-layer semiconductor substrate 241, a top-layer semiconductor device layer 243, and a third lower connection pad 249. According to an embodiment, the top-layer semiconductor chip 240 may not include a through electrode.

According to an embodiment, the thickness of the top-layer semiconductor chip 240 in the vertical direction (e.g., the Z-axis direction) may be greater than the thickness of each of the plurality of second semiconductor chips 230 in the vertical direction (e.g., the Z-axis direction). For example, as shown in an embodiment of FIG. 3, a height h2 of the top-layer semiconductor chip 240 may be greater than a height h1 of the second semiconductor chip 230. In addition, according to an embodiment, a horizontal width w4 (e.g., length in the X-axis direction and/or the Y-axis direction) of the top-layer semiconductor chip 240 may be the same as the second horizontal width w2 of the second semiconductor chip 230. However, embodiments of the present inventive concept are not necessarily limited thereto.

For example, as shown in an embodiment of FIG. 1, the plurality of second semiconductor chips 230 may be alternately stacked with the plurality of first semiconductor chips 220 (e.g., in the Z-axis direction), and the top-layer semiconductor chip 240 may be stacked on the uppermost first semiconductor chip 220, such that a total of three second semiconductor chips 230 and one top-layer semiconductor chip 240 are provided. However, embodiments of the present inventive concept are not necessarily limited thereto and the number of second semiconductor chips 230 may vary. For example, the number of second semiconductor chips 230 may be 5, 7, or the like according to the number of stacks of the chip-stacked structure 200.

In an embodiment, the plurality of first semiconductor chips 220, the plurality of second semiconductor chips 230, and the top-layer semiconductor chip 240 stacked in the vertical direction (e.g., the Z-axis direction) may be stacked through a second bump 252 and an adhesive layer 254.

In an embodiment, the lowermost first semiconductor chip 220 among the plurality of first semiconductor chips 220 may be stacked on the base chip 210 through the second bump 252 in a flip chip manner. The second bump 252 may be between the first lower connection pad 229 of the lowermost first semiconductor chip 220 and an upper connection pad 212 of the base chip 210 (e.g., directly therebetween in the Z-axis direction) and electrically connect the first lower connection pad 229 to the upper connection pad 212. In an embodiment, the second bump 252 may be between the first lower connection pad 229 and the upper connection pad 212 (e.g., directly therebetween in the Z-axis direction) and connected therebetween by thermal compression bonding (TCB).

In an embodiment, the second semiconductor chip 230 may be stacked on the first semiconductor chip 220 through the second bump 252 in a flip chip manner. The second bump 252 may be between the first upper connection pad 227 of the first semiconductor chip 220 and the second lower connection pad 239 of the second semiconductor chip 230 (e.g., directly therebetween in the Z-axis direction) and electrically connect the first upper connection pad 227 to the second lower connection pad 239.

In the chip-stacked structure 200, since the first semiconductor chip 220 and the second semiconductor chip 230 are alternately and repetitively stacked (e.g., in the Z-axis direction), the first semiconductor chip 220 may be stacked on the upper surface of the second semiconductor chip 230 through the second bump 252 in a flip chip manner again. The second bump 252 may be between the second upper connection pad 237 of the second semiconductor chip 230 and the first lower connection pad 229 of the first semiconductor chip 220 (e.g., directly therebetween in the Z-axis direction) and electrically connect the second upper connection pad 237 to the first lower connection pad 229.

In an embodiment, the top-layer semiconductor chip 240 may be stacked on the uppermost first semiconductor chip 220 in the chip-stacked structure 200 through the second bump 252 in a flip chip manner. The second bump 252 may be between the first upper connection pad 227 of the first semiconductor chip 220 and the third lower connection pad 249 of the top-layer semiconductor chip 240 (e.g., directly therebetween in the Z-axis direction) and electrically connect the first upper connection pad 227 to the third lower connection pad 249. The second bump 252 may include, for example, a micro-bump. According to an embodiment, the second bump 252 may include a pillar structure, a ball structure, or a solder layer.

The adhesive layer 254 may be between the base chip 210 and the lowermost first semiconductor chip 220 (e.g., directly therebetween in the Z-axis direction), between each first semiconductor chip 220 and each second semiconductor chip 230 (e.g. directly therebetween in the Z-axis direction), and between the uppermost first semiconductor chip 220 and the top-layer semiconductor chip 240 (e.g., directly therebetween in the Z-axis direction). For example, the adhesive layer 254 may be disposed directly between each of the adjacent semiconductor chips of the alternately stacked plurality of first semiconductor chips 220 and the plurality of second semiconductor chips 230. In some embodiments, the adhesive layer 254 may include a film having a self-adhesive characteristic. For example, the adhesive layer 254 may include a non-conductive film (NCF).

As described above, the chip-stacked structure 200 may be formed by alternately stacking the first semiconductor chip 220 and the second semiconductor chip 230, having different horizontal widths, in the vertical direction (e.g., the Z-axis direction). The second horizontal width w2 of the second semiconductor chip 230 may be greater than the first horizontal width w1 of the first semiconductor chip 220. The first semiconductor chip 220 and the second semiconductor chip 230 may be vertically stacked such that the centers thereof in the horizontal direction (the X-axis direction and/or the Y-axis direction) overlap each other (e.g., in a vertical direction, such as the Z-axis direction). For example, as shown in an embodiment of FIG. 2, when a first side surface 220a and a second side surface 220b of the first semiconductor chip 220 respectively correspond to a third side surface 230a and a fourth side surface 230b of the second semiconductor chip 230 stacked on the first semiconductor chip 220, a horizontal distance d between the first side surface 220a and the third side surface 230a may be the same as the horizontal distance d between the second side surface 220b and the fourth side surface 230b.

In an embodiment, even if the first horizontal width w1 differs from the second horizontal width w2, the horizontal width of the first core area 223C of the first semiconductor chip 220 may be substantially the same as the horizontal width of the second core area 233C of the second semiconductor chip 230. The first semiconductor chip 220 and the second semiconductor chip 230 may be disposed such that the first core area 223C overlaps the second core area 233C (e.g., in the Z-axis direction).

As described above, the adhesive layer 254 may be between the first semiconductor chip 220 and the second semiconductor chip 230 (e.g., directly therebetween in the Z-axis direction) to bond the second semiconductor chip 230 to the first semiconductor chip 220. When the second semiconductor chip 230 is bonded to the first semiconductor chip 220 through a thermal compression process, the adhesive layer 254 may protrude from the first semiconductor chip 220 in the horizontal direction (e.g., the X-axis direction and/or the Y-axis direction).

A horizontal width w3 (e.g., length in the X-axis direction and/or the Y-axis direction) of the adhesive layer 254 may correspond to a horizontal width including a fillet portion 254F occurring in (e.g., formed by) a thermal compression process. In an embodiment, the horizontal width w3 of the adhesive layer 254 may be greater than the first horizontal width w1 of the first semiconductor chip 220 and substantially the same as the second horizontal width w2 of the second semiconductor chip 230. The difference between the second horizontal width w2 and the first horizontal width w1 may be substantially the same as the horizontal width of the fillet portion 254F extending in the horizontal direction (e.g., the X-axis direction and/or the Y-axis direction) by a thermal compression process. For example, in an embodiment the difference between the second horizontal width w2 and the first horizontal width w1 may be about 400 μm. In this embodiment, the first semiconductor chip 220 and the second semiconductor chip 230 may be disposed such that each of the horizontal distance d between the first side surface 220a and the third side surface 230a and the horizontal distance d between the second side surface 220b and the fourth side surface 230b is about 200 μm. According to an embodiment, the second semiconductor chip 230 may be disposed such that the side surfaces of the second semiconductor chip 230 are aligned with the side surfaces of the adhesive layer 254 (e.g., aligned along the Z-axis direction). For example, when the second horizontal width w2 of the second semiconductor chip 230 is substantially the same as the horizontal width w3 of the adhesive layer 254, the side surfaces of the second semiconductor chip 230 may be aligned with the side surfaces of the adhesive layer 254.

An adhesive relationship between the uppermost first semiconductor chip 220 and the top-layer semiconductor chip 240 is substantially the same as an adhesive relationship between the first semiconductor chip 220 and the second semiconductor chip 230, and thus, a description thereof is omitted herein.

The molding member 290 of the semiconductor package 10 may be formed to surround the chip-stacked structure 200 on the upper surface of the lower substrate 100. In an embodiment, the molding member 290 may be formed of a molding material, such as an epoxy mold compound (EMC), or a photosensitive material, such as a photoimageable encapsulant (PIE). In some embodiments, a portion of the molding member 290 may be formed of an insulating material, such as a silicon oxide film, a silicon nitride film, or a silicon oxynitride film. However, the molding member 290 is not necessarily limited thereto and may be formed of a thermosetting resin, such as an epoxy resin, a thermoplastic resin, such as polyimide, or a resin including a reinforcing material, such as an inorganic filler, in addition thereto, particularly, an Ajinomoto build-up film (ABF), FR-4, BT, or the like.

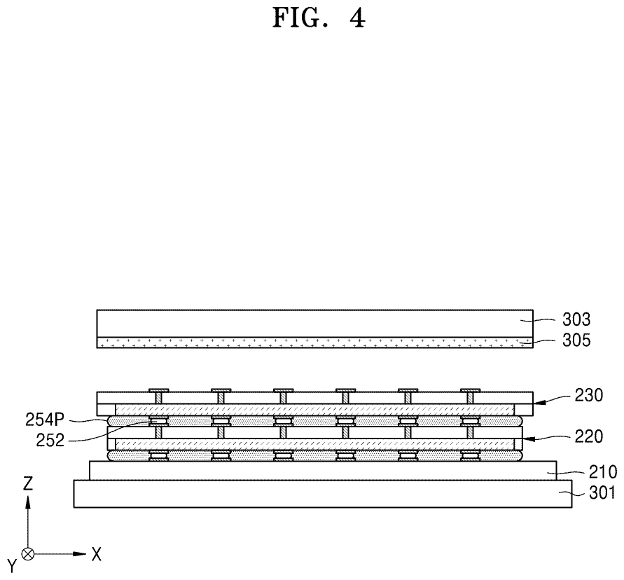

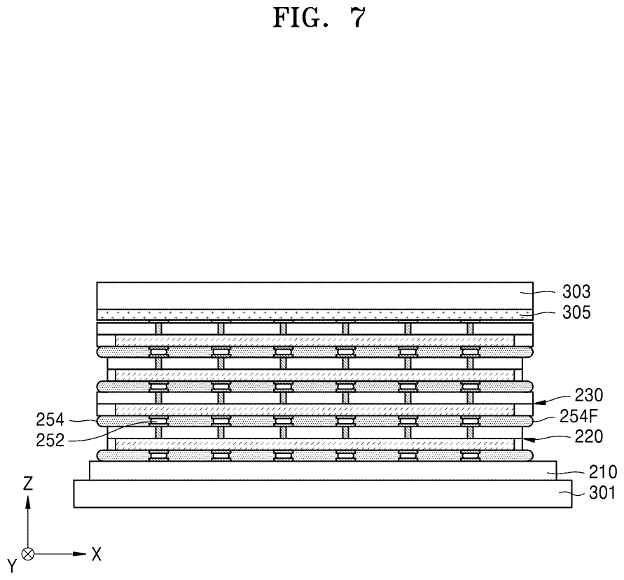

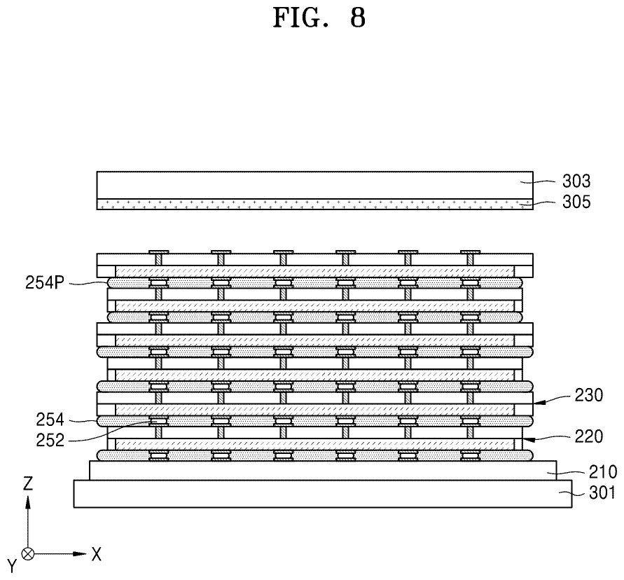

FIGS. 4 to 11 are cross-sectional views schematically illustrating, in a process order, a method of manufacturing the chip-stacked structure 200, according to an embodiment.

Referring to FIGS. 1 and 4, the lower substrate 100, the first semiconductor chip 220, and the second semiconductor chip 230 are sequentially stacked (e.g., in the Z-axis direction) and prepared on a bonding chuck 301. A preliminary adhesive layer 254P may be disposed between the lower substrate 100 and the first semiconductor chip 220 (e.g., disposed directly therebetween in the Z-axis direction) and between the first semiconductor chip 220 and the second semiconductor chip 230 (e.g., disposed directly therebetween in the Z-axis direction). The preliminary adhesive layer 254P may include an NCF.

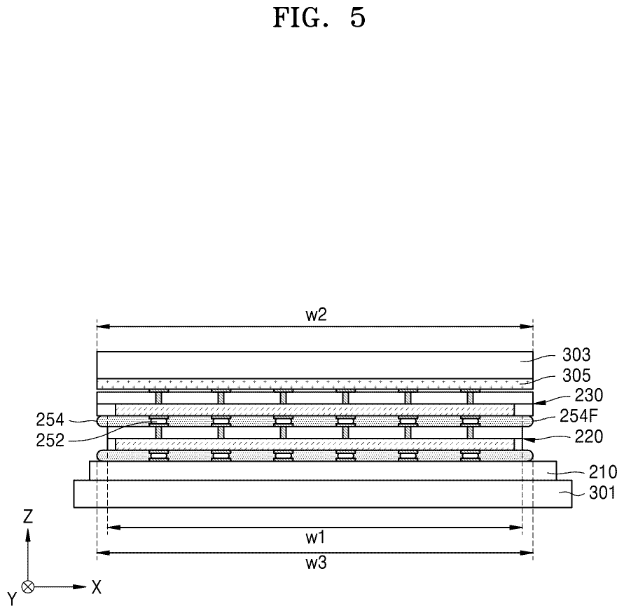

Referring to FIG. 5, heat and pressure may be applied onto the lower substrate 100, the first semiconductor chip 220, and the second semiconductor chip 230 to bond the lower substrate 100, the first semiconductor chip 220, and the second semiconductor chip 230 to each other. In an embodiment, due to thermal compression, the preliminary adhesive layer 254P (see FIG. 4) may form the adhesive layer 254 having the horizontal width w3 with the fillet portion 254F.

In a thermal compression process, the preliminary adhesive layer 254P (see FIG. 4) between the first semiconductor chip 220 and the second semiconductor chip 230 receives heat from a bonding head 303 sequentially through a head adhesive layer 305 and the second semiconductor chip 230. In an embodiment, the head adhesive layer 305 may be, for example, a Teflon tape. Since the second horizontal width w2 of the second semiconductor chip 230 is greater than the first horizontal width w1 of the first semiconductor chip 220, the preliminary adhesive layer 254P (see FIG. 4) may receive relatively uniform heat at an edge portion and a central portion thereof. Therefore, the temperature difference between the central portion and the edge portion of the preliminary adhesive layer 254P (see FIG. 4) may decrease, thereby preventing the occurrence of non-wet that is an adhesive failure which may occur at the edge portion due to the temperature difference.

After the thermal compression process, the adhesive layer 254 may include the fillet portion 254F extending from both sides thereof in the horizontal direction (e.g., the X-axis direction and/or the Y-axis direction). The second horizontal width w2 of the second semiconductor chip 230 may be substantially the same as the horizontal width w3 of the adhesive layer 254 including the fillet portion 254F.

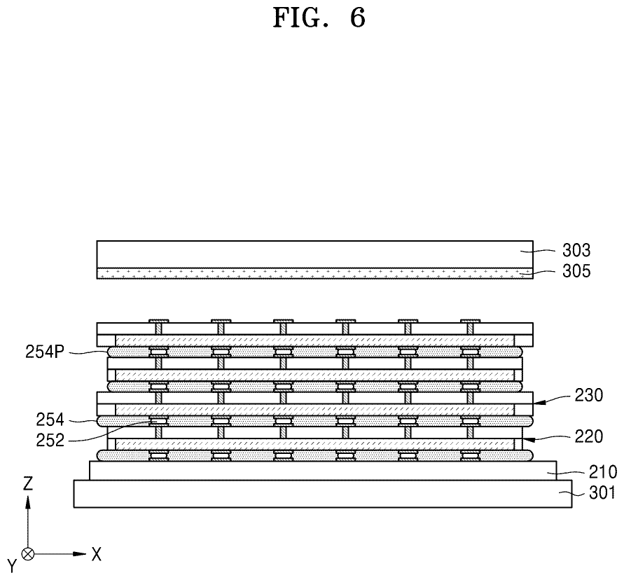

Referring to FIGS. 6 to 9, the preliminary adhesive layer 254P, the first semiconductor chip 220, the preliminary adhesive layer 254P, and the second semiconductor chip 230 are sequentially stacked and prepared on the upper surface of the uppermost second semiconductor chip 230 of the result of FIG. 5, and a thermal compression process is performed thereon. The processes of FIGS. 6 to 9 are repetitions of the process described with reference to FIGS. 4 and 5, and thus, a detailed explanation thereof is omitted for economy of description.

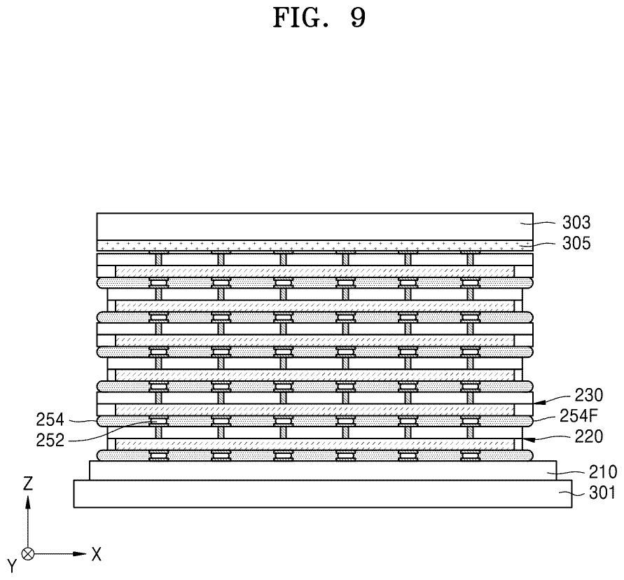

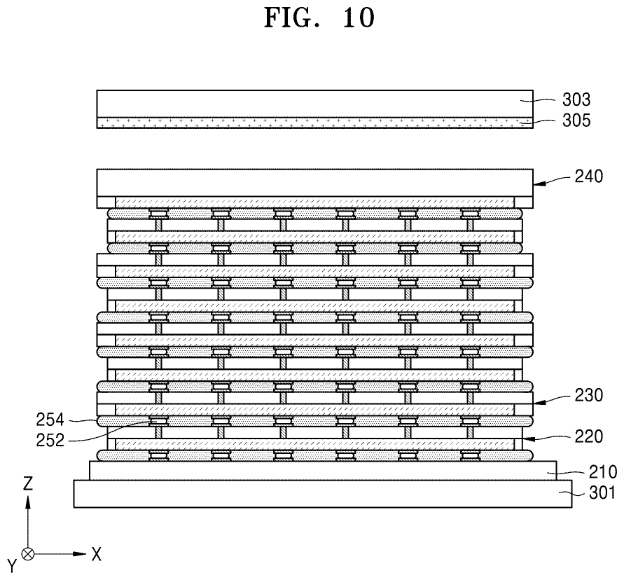

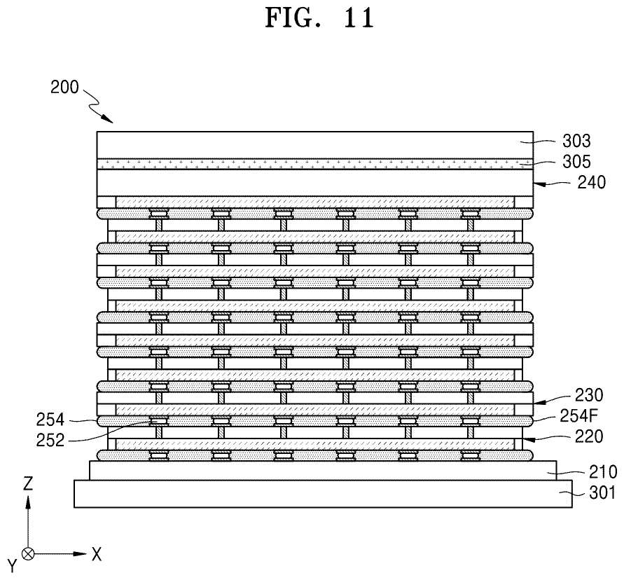

Referring to FIGS. 10 and 11, the preliminary adhesive layer 254P, the first semiconductor chip 220, the preliminary adhesive layer 254P, and the top-layer semiconductor chip 240 are sequentially stacked and prepared on the upper surface of the uppermost second semiconductor chip 230 of the result of FIG. 9, and a thermal compression process is performed thereon. The process of FIGS. 10 and 11 corresponds to a repetition of the process described with reference to FIGS. 4 and 5 except that the top-layer semiconductor chip 240 is stacked on the first semiconductor chip 220 instead of a second semiconductor chip 230, and thus, a detailed description thereof is omitted.

The semiconductor package 10 of FIG. 1 may be provided by attaching the resulting product of FIG. 11 onto the lower substrate 100 by using the first bump 170 and the under-fill material layer 180, and then forming the molding member 290.

In the semiconductor package 10 according to an embodiment of the present inventive concept, the horizontal width of a semiconductor chip (e.g., a second semiconductor chip) disposed on an even layer may be greater than the horizontal width of a semiconductor chip (e.g., a first semiconductor chip) disposed on an odd layer to provide uniform heat to an edge portion and a central portion of an adhesive layer in a thermal compression process, thereby preventing the occurrence of non-wet and providing semiconductor chips with increased reliability. However, the semiconductor package 10 is not necessarily limited thereto, and the horizontal width of a semiconductor chip disposed on an odd layer may be greater than the horizontal width of a semiconductor chip disposed on an even layer in some embodiments.

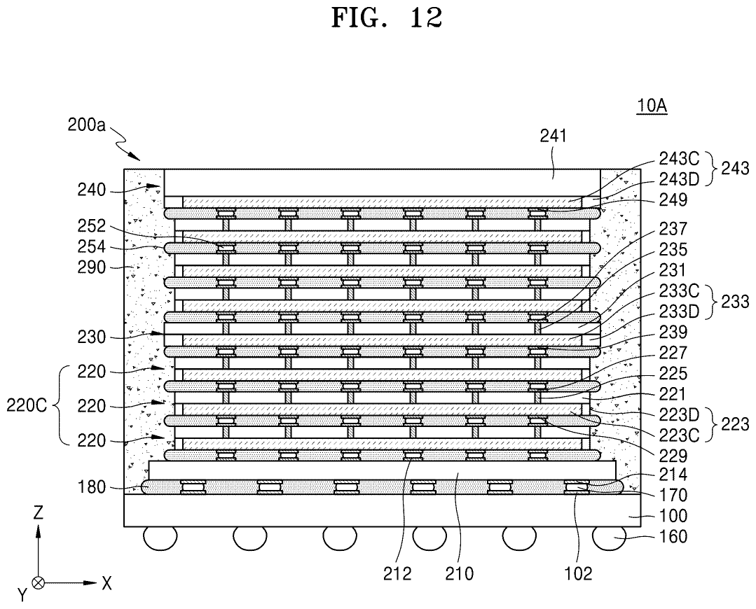

FIG. 12 is a cross-sectional view schematically illustrating a semiconductor package 10A according to an embodiment. Most components constituting the semiconductor package 10A to be described below and materials forming the components are the same as or similar to those described above with reference to FIGS. 1 to 3. Therefore, for convenience of description, differences between the semiconductor package 10A of FIG. 12 and the semiconductor package 10 of FIG. 1 are mainly described.

In an embodiment, the semiconductor package 10A according to an embodiment may include the lower substrate 100, the external connection terminal 160, a chip-stacked structure 200a, and the molding member 290.

The chip-stacked structure 200a may be on the upper surface of the lower substrate 100. In an embodiment, the chip-stacked structure 200a may include the base chip 210, a plurality of first semiconductor chip structures 220C, a plurality of second semiconductor chips 230, and the top-layer semiconductor chip 240.

The first semiconductor chip structure 220C and the second semiconductor chip 230 may be alternately stacked on the base chip 210 (e.g., in the Z-axis direction). The first semiconductor chip structure 220C may be defined as a structure formed by vertically stacking a plurality of first semiconductor chips 220. Each of the plurality of first semiconductor chips 220 constituting the first semiconductor chip structure 220C may have the first horizontal width w1. For example, as shown in FIG. 12, the first semiconductor chip structure 220C may include three first semiconductor chips 220. However, embodiments of the present inventive concept are not necessarily limited thereto and the number of the semiconductor chips 220 in the first semiconductor chip structure 220C may vary.

The second semiconductor chip 230 stacked on the upper surface of the first semiconductor chip structure 220C may have the second horizontal width w2 that is greater than the first horizontal width w1.

The first semiconductor chip structure 220C may be stacked on the second semiconductor chip 230, and the top-layer semiconductor chip 240 may be stacked on the upper surface of the uppermost first semiconductor chip structure 220C. For example, as shown in an embodiment of FIG. 12, the first semiconductor chip structure 220C may include three first semiconductor chips 220, and the chip-stacked structure 200a may include a total of six first semiconductor chips 220, one second semiconductor chip 230, and one top-layer semiconductor chip 240. However, the configuration of the chip-stacked structure 200a is not necessarily limited thereto. For example, the chip-stacked structure 200a may include three first semiconductor chip structures 220C, such as a total of nine first semiconductor chips 220, two second semiconductor chips 230, and one top-layer semiconductor chip 240.

The second bump 252 and the adhesive layer 254 may be between every two adjacent first semiconductor chips 220 (e.g., disposed directly therebetween in the Z-axis direction), between the first semiconductor chip 220 and the second semiconductor chip 230 (e.g., disposed directly therebetween in the Z-axis direction), and between the first semiconductor chip 220 and the top-layer semiconductor chip 240 (e.g., disposed directly therebetween in the Z-axis direction).

The horizontal width w3 of the adhesive layer 254 may correspond to a horizontal width including the fillet portion 254F occurring in a thermal compression process. In an embodiment, the horizontal width w3 of the adhesive layer 254 may be greater than the first horizontal width w1 of the first semiconductor chip 220 and substantially the same as the second horizontal width w2 of the second semiconductor chip 230. The difference between the second horizontal width w2 and the first horizontal width w1 may be substantially the same as the horizontal width of the fillet portion 254F extending in the horizontal direction (e.g., the X-axis direction and/or the Y-axis direction) by a thermal compression process. According to an embodiment, the second semiconductor chip 230 may be disposed such that the side surfaces of the second semiconductor chip 230 are aligned with the side surfaces of the adhesive layer 254 (e.g., along the Z-axis direction).

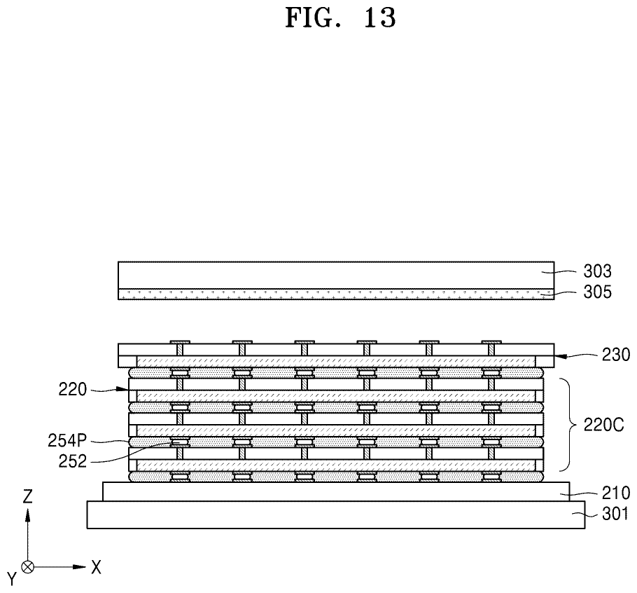

FIGS. 13 to 16 are cross-sectional views schematically illustrating, in a process order, a method of manufacturing the chip-stacked structure 200a, according to embodiments of the present inventive concept.

Referring to FIGS. 12 and 13, the lower substrate 100, the first semiconductor chip structure 220C, and the second semiconductor chip 230 are sequentially stacked and prepared on the bonding chuck 301. The preliminary adhesive layer 254P may be between the lower substrate 100 and the first semiconductor chip 220 (e.g., disposed directly therebetween in the Z-axis direction), between every two adjacent first semiconductor chips 220 (e.g., disposed directly therebetween in the Z-axis direction), and between the first semiconductor chip 220 and the second semiconductor chip 230 (e.g., disposed directly therebetween in the Z-axis direction). For example, in an embodiment the preliminary adhesive layer 254P may include an NCF.

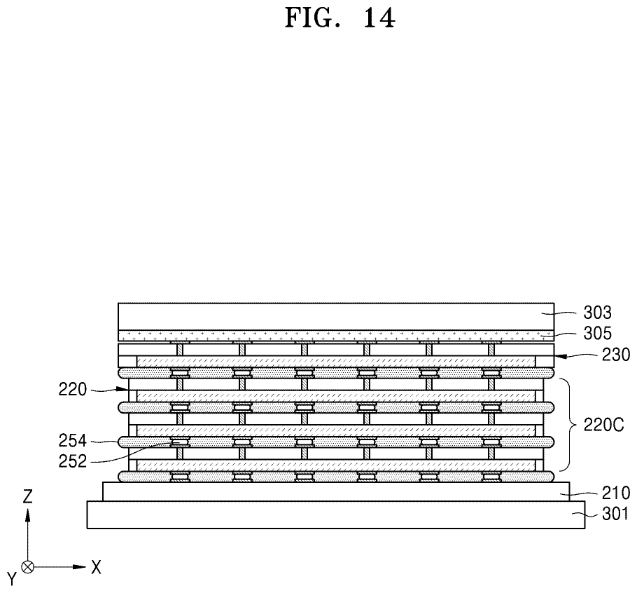

Referring to FIG. 14, heat and pressure may be applied to bond the lower substrate 100, the first semiconductor chip structure 220C, and the second semiconductor chip 230 to each other. In an embodiment, due to the thermal compression, the preliminary adhesive layer 254P (see FIG. 13) may form the adhesive layer 254 having the horizontal width w3 with the fillet portion 254F.

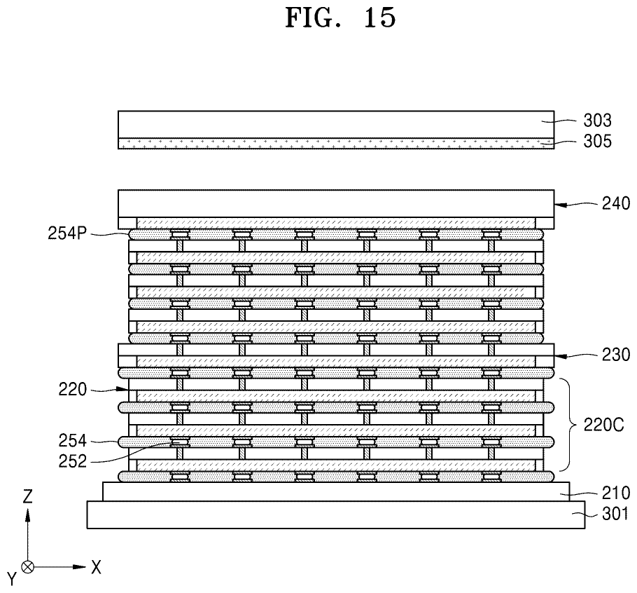

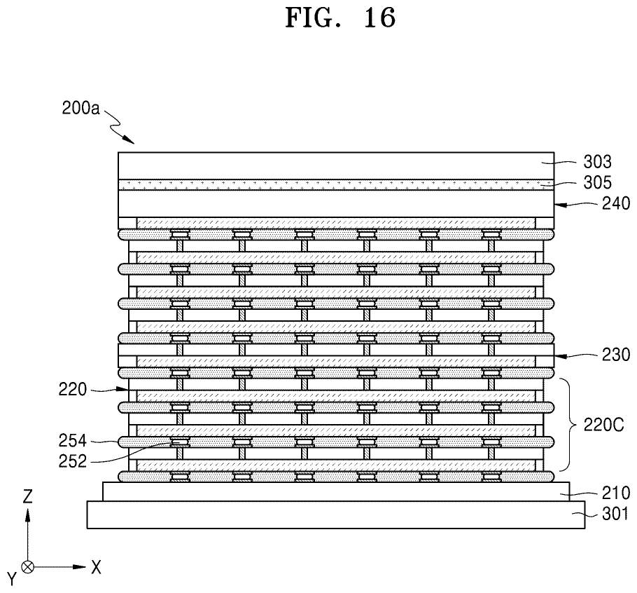

Referring to FIGS. 15 and 16, the preliminary adhesive layer 254P, the first semiconductor chip structure 220C, the preliminary adhesive layer 254P, and the top-layer semiconductor chip 240 are sequentially stacked and prepared on the upper surface of the uppermost second semiconductor chip 230 of the resulting product of FIG. 14, and a thermal compression process is performed thereon. The process of FIGS. 15 and 16 corresponds to a repetition of the process described with reference to FIGS. 13 and 14 except that the top-layer semiconductor chip 240 is disposed on the first semiconductor chip structure 220C instead of a second semiconductor chip 230, and thus, a detailed description thereof is omitted for economy of description.

In the semiconductor package 10A according to an embodiment of the present inventive concept, the horizontal width of a semiconductor chip (e.g., a second semiconductor chip) disposed at every four stacks may be greater than the horizontal width of each of the other semiconductor chips (e.g., first semiconductor chips) to provide uniform heat to an edge portion and a central portion of an adhesive layer in a thermal compression process, thereby preventing the occurrence of non-wet and providing semiconductor chips with an increased reliability. However, embodiments of the present inventive concept are not necessarily limited to a stack including four first semiconductor chips and one second semiconductor chip, and the number of first semiconductor chips may be variously modified.

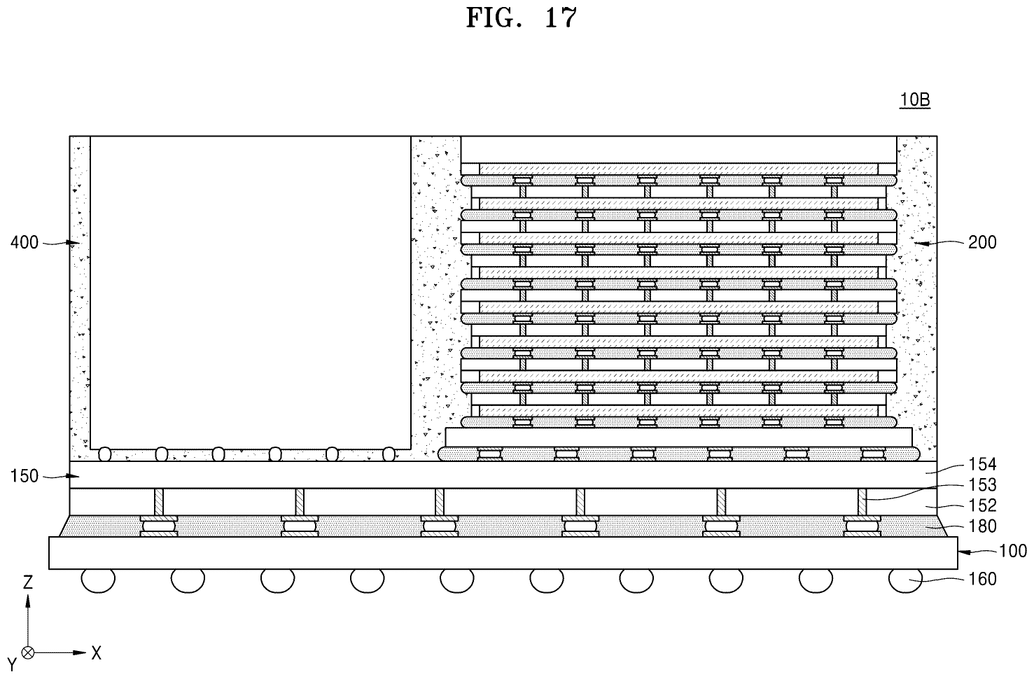

FIG. 17 is a cross-sectional view schematically illustrating a semiconductor package 10B according to an embodiment. Hereinafter, differences between the semiconductor package 10B of FIG. 17 and the semiconductor package 10 of FIG. 1 are mainly described by referring to the semiconductor package 10 described with reference to FIG. 1.

Referring to FIG. 17, in an embodiment the semiconductor package 10B may include the lower substrate 100, an interposer substrate 150, the chip-stacked structure 200, and a semiconductor chip 400.

According to an embodiment, the interposer substrate 150 may be on the lower substrate 100. In an embodiment, the interposer substrate 150 may be formed based on Si and electrically connect the chip-stacked structure 200 to the semiconductor chip 400. According to an embodiment, the interposer substrate 150 may be electrically connected to the lower substrate 100 via a bump. The under-fill material layer 180 surrounding the bump may be between the lower substrate 100 and the interposer substrate 150. In an embodiment, the under-fill material layer 180 may be formed of an epoxy resin formed by, for example, a capillary under-fill process. However, in some embodiments, the molding member 290 may directly fill the gap between the lower substrate 100 and the interposer substrate 150 by a molded under-fill process. In this embodiment, the under-fill material layer 180 may be omitted.

The interposer substrate 150 may include a body layer 152 and a wiring layer 154. The wiring layer 154 may be on the upper surface of the body layer 152. In an embodiment, the wiring layer 154 may include a wiring pattern. The wiring pattern may electrically connect the chip-stacked structure 200 to the semiconductor chip 400 or electrically connect between the chip-stacked structure 200 and a through electrode 153 and between the semiconductor chip 400 and the through electrode 153.

The through electrode 153 may be formed in the body layer 152. The through electrode 153 may pass through the body layer 152 in the vertical direction (e.g., the Z direction). According to an embodiment, the through electrode 153 may include a TSV. The through electrode 153 may be electrically connected to the bump via a pad formed on the lower surface of the body layer 152.

Each of the chip-stacked structure 200 and the semiconductor chip 400 may be on the upper surface of the interposer substrate 150. The chip-stacked structure 200 is substantially the same as or similar to that described with reference to FIG. 1, and thus, a description thereof is omitted for economy of description.

The semiconductor chip 400 may be on the upper surface of the interposer substrate 150 and spaced apart from the chip-stacked structure 200 in the first horizontal direction (e.g., the X-axis direction). According to an embodiment, the semiconductor chip 400 may include a logic chip. The logic chip may include a microprocessor, such as a CPU, a GPU, or an AP, an analog device, or a digital signal processor. However, the semiconductor chip 400 is not necessarily limited to the logic chip and may include a memory chip. In an embodiment, the memory chip may be, for example, a volatile memory chip, such as DRAM or SRAM, or a non-volatile memory chip, such as PRAM, MRAM, FeRAM, or RRAM.

While the present inventive concept has been particularly shown and described with reference to non-limiting embodiments thereof, it will be understood that various changes in form and details may be made therein without departing from the spirit and scope of the present inventive concept.

What is claimed is:

1. A semiconductor package comprising:
a base chip;
a plurality of first semiconductor chips each having a first horizontal width; and
a plurality of second semiconductor chips each having a second horizontal width that is different from the first horizontal width,
wherein the plurality of first semiconductor chips and the plurality of second semiconductor chips are alternately stacked on the base chip, and an adhesive layer is between adjacent semiconductor chips of the alternately stacked plurality of first semiconductor chips and second semiconductor chips.

2. The semiconductor package of claim 1, wherein the second horizontal width is greater than the first horizontal width.

3. The semiconductor package of claim 1, wherein:
the adhesive layer comprises a fillet portion extending in a horizontal direction, wherein the fillet portion is formed by a thermal compression process; and
a difference between the second horizontal width and the first horizontal width is substantially same as a horizontal width of the fillet portion.

4. The semiconductor package of claim 1, wherein:
the first horizontal width is less than a horizontal width of the adhesive layer; and
the second horizontal width is substantially same as the horizontal width of the adhesive layer.

5. The semiconductor package of claim 1, wherein side surfaces of each second semiconductor chip are aligned with side surfaces of the adhesive layer.

6. The semiconductor package of claim 1, wherein the plurality of first semiconductor chips and the plurality of second semiconductor chips are vertically stacked such that horizontal centers of the plurality of first semiconductor chips and the plurality of second semiconductor chips overlap each other in a vertical direction.

7. The semiconductor package of claim 1, wherein:
each of the plurality of first semiconductor chips comprises a first side surface and a second side surface facing each other;
each of the plurality of second semiconductor chips comprises a third side surface corresponding to the first side surface and a fourth side surface corresponding to the second side surface; and
each of the plurality of second semiconductor chips is on each of the plurality of first semiconductor chips, wherein a horizontal distance between the first side surface and the third side surface is substantially same as a horizontal distance between the second side surface and the fourth side surface.

8. The semiconductor package of claim 1, wherein:
each first semiconductor chip of the plurality of first semiconductor chips comprises a first core area having individual devices thereon;
each second semiconductor chip of the plurality of second semiconductor chips comprises a second core area having individual devices thereon; and
the first core area has a horizontal width that is substantially same as a horizontal width of the second core area.

9. The semiconductor package of claim 1, wherein:
a bump is between each first semiconductor chip of the plurality of first semiconductor chips and each second semiconductor chip of the plurality of second semiconductor chips;
each bump electrically connects the first semiconductor chip to the second semiconductor chip; and
the adhesive layer is between the first semiconductor chip and the second semiconductor chip to surround the bump.

10. The semiconductor package of claim 1, wherein the adhesive layer comprises a non-conductive film (NCF).

11. The semiconductor package of claim 1, further comprising:
a top-layer semiconductor chip on an uppermost first semiconductor chip among the plurality of first semiconductor chips;
a horizontal width of the top-layer semiconductor chip is substantially same as the second horizontal width; and
a height of the top-layer semiconductor chip is greater than a height of each second semiconductor chip of the plurality of second semiconductor chips.

12. The semiconductor package of claim 1, wherein a horizontal width of the base chip is greater than each of the first horizontal width and the second horizontal width.

13. A semiconductor package comprising:
a lower substrate having an external connection terminal on a lower surface thereof;
a base chip on the lower substrate;
a plurality of first semiconductor chips each having a first horizontal width;
a plurality of second semiconductor chips each having a second horizontal width that is greater than the first horizontal width;
a top-layer semiconductor chip having a height that is greater than a height of each second semiconductor chip of the plurality of second semiconductor chips and having a same horizontal width as the second horizontal width;
an adhesive layer between adjacent semiconductor chips of the plurality of first semiconductor chips and the plurality of second semiconductor chips and between an uppermost first semiconductor chip among the plurality of first semiconductor chips and the top-layer semiconductor chip, the adhesive layer including a fillet portion extending in a horizontal direction; and
a molding member filling gaps among the base chip, the plurality of first semiconductor chips, the plurality of second semiconductor chips, the top-layer semiconductor chip, and the adhesive layer on the lower substrate,
wherein the plurality of first semiconductor chips and the plurality of second semiconductor chips are alternately stacked on the base chip, the top-layer semiconductor chip is on the uppermost first semiconductor chip among the plurality of first semiconductor chips, the first horizontal width is less than a horizontal width of the adhesive layer, the second horizontal width is substantially same as the horizontal width of the adhesive layer, a difference between the second horizontal width and the first horizontal width is substantially same as a horizontal width of the fillet portion, and the plurality of first semiconductor chips, the plurality of second semiconductor chips, and the top-layer semiconductor chip are vertically stacked such that centers thereof in a horizontal direction overlap each other in a vertical direction.

14. The semiconductor package of claim 13, wherein an interposer substrate is on the lower substrate, the base chip and a semiconductor chip spaced apart from the base chip in the horizontal direction are on the interposer substrate, the interposer substrate comprises a body layer, a wiring layer, and a through electrode passing through the body layer in the vertical direction, and the wiring layer comprises a wiring pattern electrically connecting the base chip to the semiconductor chip.

15. A semiconductor package comprising:
a base chip;
a plurality of first semiconductor chips each having a first horizontal width; and
a plurality of second semiconductor chips each having a second horizontal width that is different from the first horizontal width,
wherein first semiconductor chip structures each including the plurality of first semiconductor chips vertically stacked and the plurality of second semiconductor chips are alternately stacked on the base chip, and an adhesive layer is between adjacent first semiconductor chips of the plurality of first semiconductor chips and between each of the first semiconductor chip structures and each of the plurality of second semiconductor chips.

16. The semiconductor package of claim 15, wherein each of the first semiconductor chip structures comprises three first semiconductor chips.

17. The semiconductor package of claim 15, wherein the second horizontal width is greater than the first horizontal width.

18. The semiconductor package of claim 15, wherein:
the adhesive layer comprises a fillet portion extending in a horizontal direction, wherein the fillet portion is formed by a thermal compression process; and
a difference between the second horizontal width and the first horizontal width is substantially same as a horizontal width of the fillet portion.

19. The semiconductor package of claim 15, wherein:
the first horizontal width is less than a horizontal width of the adhesive layer; and the second horizontal width is substantially same as the horizontal width of the adhesive layer.

20. The semiconductor package of claim 15, wherein side surfaces of each second semiconductor chip are aligned with side surfaces of the adhesive layer.
